(19) United States
(12) Patent Application Publication
(10) Pub. No.: US 2012/0068334 A1
(43) Pub. Date: Mar. 22, 2012

(54) SEMICONDUCTOR DEVICE AND MANUFACTURING METHOD THEREOF

(75) Inventors: Tatsuo MIGITA, Oita (JP); Hirokazu Ezawa, Tokyo (JP); Soichi Yamashita, Kanagawa (JP)

(73) Assignee: Kabushiki Kaisha Toshiba, Tokyo (JP)

(21) Appl. No.: 13/225,806

(22) Filed: Sep. 6, 2011

(30) Foreign Application Priority Data
Sep. 22, 2010 (JP) 2010-212781

(51) Int. Cl. H01L 23/488; H01L 21/285; H01L 21/288; H01L 21/283

(52) U.S. Cl. 257/737; 438/613; 257/E23.023; 257/E21.159; 257/E21.16; 257/E21.174

(57) ABSTRACT

Semiconductor devices of embodiments include a plurality of solder bumps electrically connected on a plurality of electrode pads disposed on a semiconductor substrate in parallel at a pitch of 40 μm or less via under bump metals. The ratio of the diameter (the top diameter) of the portion of each solder bump most away from the semiconductor substrate and the diameter (the bottom diameter) of the bottom side of each solder bump is 1:1 to 1:4.

### CROSS-REFERENCE TO RELATED APPLICATIONS

This application is based upon and claims the benefit of priority from the prior Japanese Patent Application No. 2010-212781, filed on Sep. 22, 2010; the entire contents of which are incorporated herein by reference.

### FIELD

The embodiments relate in general to semiconductor devices and manufacturing methods thereof.

### BACKGROUND

Recently, it is required to improve an operation speed of a device and to increase a capacity of a memory to achieve high integration and sophisticated function of a semiconductor device. In some devices, a chip, in which logic and a large capacity DRAM are packaged by Chip on Chip (CoC) connection, has been developed in place of one chip eDRAM.

When a minute bump for CoC connection is formed, a bump having a high aspect ratio may be required in consideration of CoC properties. At the time, a solder bump is formed via a pillar of Cu, Ni, Au, and the like. In the CoC connection, the bump pitch is recently more miniaturized and is becoming to 40 μm, 30μm.

### BRIEF DESCRIPTION OF THE DRAWINGS

FIG. 1A is a view illustrating a semiconductor device and a manufacturing method of the semiconductor device of a first embodiment;

FIG. 1B is a view illustrating the semiconductor device and a manufacturing method of the semiconductor device of the first embodiment;

FIG. 1C is a view illustrating the semiconductor device and a manufacturing method of the semiconductor device of the first embodiment;

FIG. 2A is a view illustrating a semiconductor device and a manufacturing method of the semiconductor device of a second embodiment;

FIG. 2B is a view illustrating the semiconductor device and a manufacturing method of the semiconductor device of the second embodiment;

FIG. 2C is a view illustrating the semiconductor device and a manufacturing method of the semiconductor device of the second embodiment;

FIG. 3A is a view illustrating a semiconductor device and a manufacturing method of the semiconductor device of a third embodiment; and

FIG. 3B is a view illustrating the semiconductor device and a manufacturing method of the semiconductor device of the third embodiment.

### DETAILED DESCRIPTION

Semiconductor devices of embodiments include a plurality of solder bumps electrically connected on a plurality of electrode pads disposed on a semiconductor substrate in parallel at a pitch of 40 μm or less via under bump metals. The ratio of the diameter (the top diameter) of the portion of each solder bump most away from the semiconductor substrate and the diameter (the bottom diameter) of the bottom side of each solder bump is 1:1 to 1:4.

The semiconductor devices and manufacturing methods of the semiconductor devices according to the embodiments will be explained below in detail referring to the accompanying drawings. The present invention is not limited to the following embodiments.

### First Embodiment

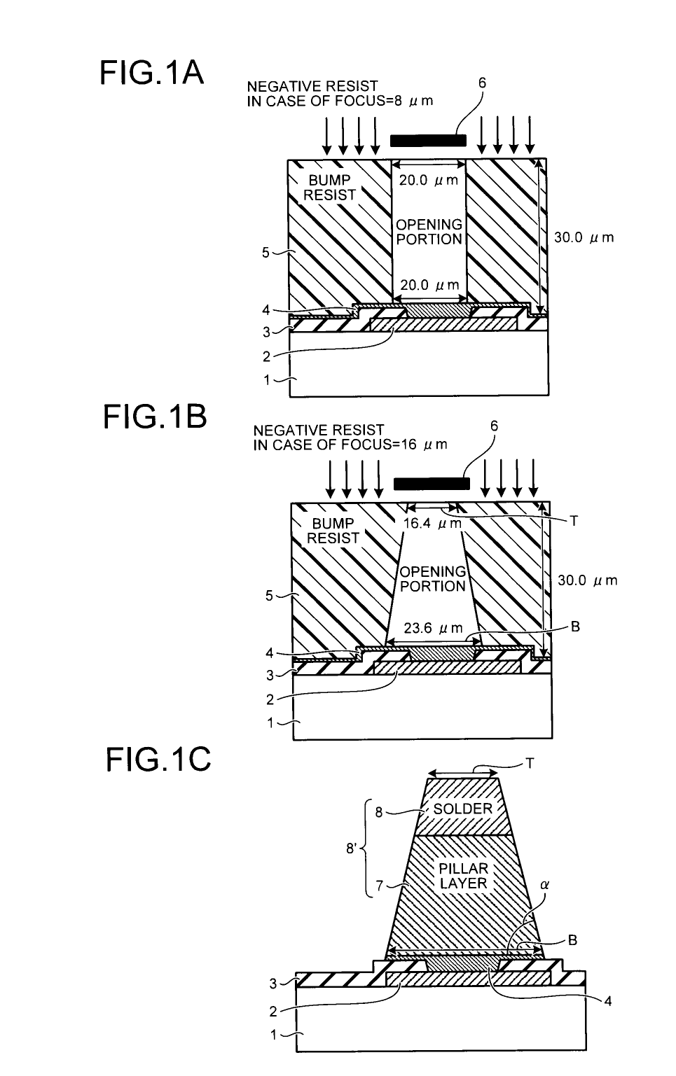

FIG. 1A to FIG. 1C are sectional views illustrating a semiconductor device and a manufacturing method of the semiconductor device of a first embodiment. In the embodiment, a minute solder bump is formed on a silicon substrate made by a conventional LSI forming technology.

First, as illustrated in FIG. 1A, for example, an aluminum electrode pad 2 is formed on a substrate 1, and further, for example, a SiN film 3 is formed as a passivation film so as to cover an edge of the electrode pad 2 and the substrate 1 while exposing a center of the electrode pad 2. In the embodiment, the electrode pad 2 and not illustrated adjacent electrode pads are disposed in parallel at an interval of 40 μm or less. Cu films or laminated films of Cu and Ti and the like are formed on the electrode pads as under bump metals 4 (UBMs) of solder bumps using sputtering, CVD, ALD (Atomic Layer Deposition), plating, and the like.

Cu is used as uppermost layers of the under bump metals 4 and the uppermost layers function as power distribution layers in a plating process which is a subsequent process. Next, to form a bump pattern, a photosensitive resist 5 is applied, exposure is performed using a photomask 6 as a mask, and a desired bump pattern is formed using a photolithography technology. As the photosensitive resist 5, for example, a negative resist is used.

Since a special opening shape can be formed by mainly and largely changing a focus condition in exposure of the photolithography technology from an ordinary straight shape (FIG. 1A), a bump pattern is formed by setting a focus value to 16 μm (FIG. 1B).

Next, a Ni pillar 7 is formed by precipitating Ni on the under bump metal 4 of a bump pattern portion by electrolytic plating and subsequently a solder 8 is precipitated by electrolytic plating. Subsequently, the photosensitive resist 5 is removed by a stripping liquid, and the under bump metal 4 is removed by etching. Thereafter, the solder 8 is melted and condensed again by a reflow process, and a solder bump 8′ is formed. At the time, since the exposure is performed by greatly changing the photolithography process from a focus value of 8 μm at which the ordinary straight shape can be obtained to the focus value of 16 μm, a bump shape which spreads toward a bottom can be obtained as illustrated in FIG. 10.

In general, a shift of a focus value in exposure from a small value to large value causes the angle between a bottom surface and a side surface of a bump shape with respect to a bump side (a of FIG. 10) to change from a large value (90° or more) to a small value (90° or less). Even if any of a negative resist and a positive resist is selected, a focus value at which α=90° is achieved is determined depending on the resist. The focus value is a focus value at which exposure is performed in the straight shape. In the embodiment, as illustrated in FIG. 10, exposure is performed at a focus value larger than a focus value at which the straight shape is exposed so that α<90° is achieved.

In a bump bottom diameter B at the time, a shape, which is 3.6 μm larger than 20 μm at which the straight shape is exposed, is obtained. When the solder bump 8′ having the above shape is formed, since the bottom area of an interface between the pillar 7 under the solder 8 and the under bump metal 4 of a ground layer can be kept about 40 larger, an intimate contact property can be improved. Further, since the top diameter T of the solder bump 8′ can be kept smaller than the bottom diameter B with respect to the bump pitch of 40 μm or less, a short-circuit risk to an adjacent bump can be reduced. As a result, even if a bump is greatly miniaturized, a solder bump having high reliability can be formed. As illustrated in FIGS. 1B and 1C, the top diameter T is the diameter of the portion of the solder bump 8′ most away from the semiconductor the substrate 1, and the bottom diameter B is the diameter of a bottom side of the solder bump 8′ illustrated in FIG. 1B and FIG. 10 likewise.

Note that it is preferable that the ratio T:B of the top diameter T and the bottom diameter B is 1:1 to 1:4 or the angle α between the bottom surface and the side surface of the bump shape with respect to the bump side is 45°<α<90°. Further, it is more preferable that both the ratio T:B and the angle a are within the above ranges.

This is because when the ratio T:B is out of the range and B becomes smaller than T or when a is out of the range and becomes 90° or more, the bottom diameter B of the bump becomes thin and the intimate contact area of the bump with the interface of the ground layer becomes small. Further, this is because a problem arises in that the top diameter T of the bump becomes relatively too large and a short-circuit risk increases when the bump is connected.

Further, this is because when B becomes four times as large as T or when a becomes 45° or less on the contrary, since the bottom diameter B of the bump becomes too thick, a short-circuit risk to an adjacent bump becomes high. Further, this is because a problem arises in that since the top diameter T of the bump becomes too small, it becomes very difficult to connect the bump.

Further, when a case, in which it is intended to increase the degree of integration of the bump, and the like are also taken into consideration, in order to reduce the short-circuit risk to the adjacent bump, it is more preferable that the ratio T:B of the top diameter T and the bottom diameter B is 1:1 to 1:3 or the angle a between the bottom surface and the side surface of the bump shape with respect to the bump side is 55°<α<90°. Further, it is more preferable that both the ratio T:B and the angle a are within the above range.

As described above, when the bump of the embodiment is formed on a semiconductor substrate on which a semiconductor device is formed, even if the pitch of the bump is formed in an ultra-minute pattern, an intimate contact property of the bump with the ground layer can be improved, a short-circuit risk between solder bumps can be reduced, and the reliability of a semiconductor package can be improved.

### Second Embodiment

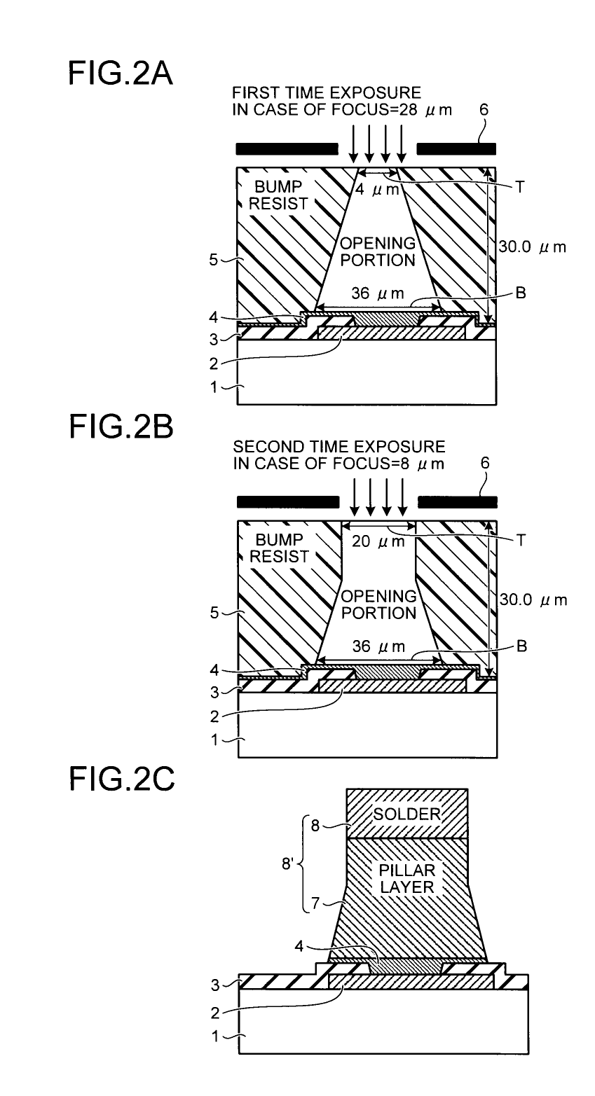

In a second embodiment of the invention, for example, a positive resist is used as a photosensitive resist 5, a focus value in exposure of a photolithography process is set to 28 μm (a first focus value) which is larger than the focus value in the first embodiment (FIG. 2A), and further the focus value is set a focus value (a second focus value) of 8 μm of an ordinarily used condition, and exposure is performed twice (FIG. 2B) to widen an opening of an upper portion of a resist. With the operation, in comparison with the first embodiment, a solder bump 8′, in which the bottom area of an interface between the solder bump 8′and an under bump metal 4 of a ground layer is larger, can be formed.

As a bump bottom diameter B at the time, a shape 16.0 μm larger than 20 μm when a straight shape is exposed can be obtained. As illustrated in FIG. 2C, when the solder bump 8′ having the above shape is formed, since the bottom area of the interface between the solder bump 8′and the under bump metal 4 of the ground layer can be kept about 220, larger, an intimate contact property can be more improved.

### Third Embodiment

Different from the first embodiment in which Ni is precipitated in the electrolytic plating on the under bump metal 4 of the bump pattern portion opened by the photoresist process, the third embodiment of the invention precipitates Cu on an under bump metal 4 of a bump pattern portion and forms a Cu pillar 9. Further, a Ni pillar 7 is formed on the Cu pillar 9, and subsequently a photosensitive resist is removed by a stripping liquid, and the under bump metal 4 is removed by etching (not illustrated).

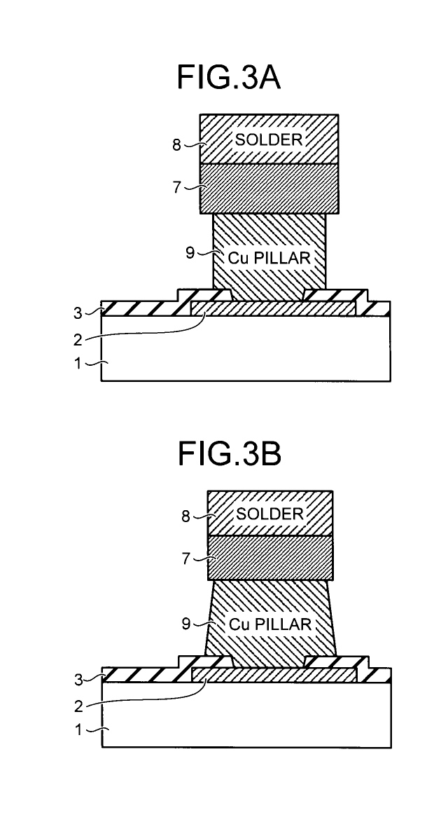

Since Cu is used as a plating power distribution material of the under bump metal 4 here, when the Cu under bump metal 4 is etched, the Cu pillar 9 is also etched at the same time (FIG. 3A). In the focus value of 8 μm in the ordinary lithography, although the Cu pillar portion 9 becomes thin and an intimate contact property is deteriorated, in the embodiment, a focus value is set to 16 μm which is larger than an ordinary value. Accordingly, a solder bump having a large bottom diameter can be formed (FIG. 3B). Further, top and bottom shapes can be arbitrarily set by performing exposure twice as in the second embodiment.

Note that, in the embodiments, although explanation is made using any resist of the negative and positive resists as the photosensitive resist 5, any resist of the negative and positive resists may be used in the respective embodiments. As described above, even if any resist of the negative and positive resists is selected, a focus value in which α=90° is achieved is determined depending on the resist. Further, a tendency that a shift of a focus value in exposure from a small value to large value causes the angle between a bottom surface and a side surface of a bump shape with respect to a bump side (α of FIG. 1C) to change from a large value (90° or more) to a small value (90° or less) is also common. Accordingly, the same advantage as that described above can be obtained by setting the focus value larger than the value at the time of the straight shape. Although a rubber resist, a resin resist such as an acrylic resist, and the like may be used as the negative resist and a resin resist such as a novolac resin resist and the like may be used as the positive resist, the negative and positive resists are not limited thereto. Further, Ni, Cu, Au, Sn, Ag, Pb, Cr or a combination thereof can be optionally selected as material for configuring the solder bump such as the solder, the pillar and the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising a plurality of solder bumps electrically connected on a plurality of electrode pads disposed on a semiconductor substrate in parallel at a pitch of 40 μm or less via under bump metals, wherein the ratio of the diameter (the top diameter) of the portion of each solder bump most away from the semiconductor substrate and the diameter (the bottom diameter) of the bottom side of each solder bump is 1:1 to 1:4.

2. The semiconductor device according to claim 1, wherein the ratio is 1:1 to 1:3.

3. The semiconductor device according to claim 1, wherein the solder bumps are composed of Ni, Cu, Au, Sn, Ag, Pb, Cr, or a combination thereof.

4. The semiconductor device according to claim 1, wherein the under bump metals are composed of a Cu film or a laminated film of Cu and Ti.

5. The semiconductor device according to claim 1, wherein the angle between a bottom side and a side surface of each solder bump with respect to a side of each solder bump is 45° to 90°.

6. The semiconductor device according to claim 2, wherein the solder bumps are composed of Ni, Cu, Au, Sn, Ag, Pb, Cr, or a combination thereof.

7. The semiconductor device according to claim 2, wherein the under bump metals are composed of a Cu film or a laminated film of Cu and Ti.

8. A semiconductor device comprising a plurality of solder bumps electrically connected on a plurality of electrode pads disposed on a semiconductor substrate in parallel at a pitch of 40 μm or less via under bump metals, wherein the angle between a bottom side and a side surface of each solder bump with respect to a side of each solder bump is 45° to 90°.

9. The semiconductor device according to claim 8, wherein the angle is 55° to 90°.

10. The semiconductor device according to claim 8, wherein the solder bumps are composed of Ni, Cu, Au, Sn, Ag, Pb, Cr, or a combination thereof.

11. The semiconductor device according to claim 8, wherein the under bump metals are composed of a Cu film or a laminated film of Cu and Ti.

12. The semiconductor device according to claim 8, wherein the ratio of the diameter (the top diameter) of the portion of each solder bump most away from the semiconductor substrate and the diameter (the bottom diameter) of the bottom side of each solder bump is 1:1 to 1:4.

13. The semiconductor device according to claim 9, wherein the solder bumps are composed of Ni, Cu, Au, Sn, Ag, Pb, Cr, or a combination thereof.

14. The semiconductor device according to claim 9, wherein the under bump metals are composed of a Cu film or a laminated film of Cu and Ti.

15. A manufacturing method of a semiconductor device comprising:
forming a resist film on a semiconductor substrate having a plurality of electrode pads formed on the semiconductor substrate at a pitch of 40 μm or less and under bump metals laminated on the electrode pads; and
performing exposure to the surface of the resist film at a first focus value larger than a focus value at which a straight shape is exposed to the surface of the resist film in a vertical direction.

16. The manufacturing method of the semiconductor device according to claim 15, wherein exposure is further performed by a second focus value at which a straight shape is exposed in a width larger than the diameter (the top diameter) of the portion, which is most away from the semiconductor substrate, of the bump-shaped portion of the resist film which is made soluble by the exposure as well as in a width smaller than the diameter (the bottom diameter) of a bottom surface of the bump-shaped portion.

17. The manufacturing method of the semiconductor device according to claim 15, wherein the resist film is composed of a positive resist.

18. The manufacturing method of the semiconductor device according to claim 15, wherein the resist film is composed of a negative resist.

19. The manufacturing method of the semiconductor device according to claim 15, wherein the under bump metals are formed by sputtering, CVD, ALD (Atomic Layer Deposition), or plating.

20. The manufacturing method of the semiconductor device according to claim 15, wherein the under bump metals are composed of a Cu film or a laminated layer of Cu and Ti.
